(19) United States
(12) Patent Application Publication
(10) Pub. No.: US 2008/0266149 A1
(43) Pub. Date: Oct. 30, 2008

(54) Modulation Code System and Methods of Encoding and Decoding a Signal

(75) Inventors: Hendrik Dirk Lodewijk Hollmann, Eindhoven (NL); Johannes Wilhelmus Maria Bergmans, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/599,612

(22) PCT Filed: Apr. 1, 2005
(86) PCT No.: PCT/IB05/51097

§ 371 Date: Oct. 3, 2006

(30) Foreign Application Priority Data
Apr. 9, 2004 (EP) 04101473.9

(51) Int. Cl. H03M 13/00

(52) U.S. Cl. 341/94

(57) ABSTRACT

The invention relates to a modulation code system and a corresponding modulation method. Said modulation system comprises an encoder 100 for transforming an original signal s into an encoded signal c satisfying predefined second constraints. Said modulation code system further comprises a decoder 200 for decoding the encoded signal c after restoration back into the original signal s. It is the object of the invention to improve such a known modulation code system and method in the way that the amount of required hardware is reduced. This object is solved according to the invention by designing the encoder 100 such that it comprises a series connection of a modulation code encoder 110 and of a transformer encoder 120 serving for filtering an intermediate signal t output by said modulation code encoder 110 and satisfying predefined first constraints in order to generate said encoder output signal c. The object is further solved by the decoder 200 comprising a series connection of a transformer decoder 220 and of a modulation code decoder 210.

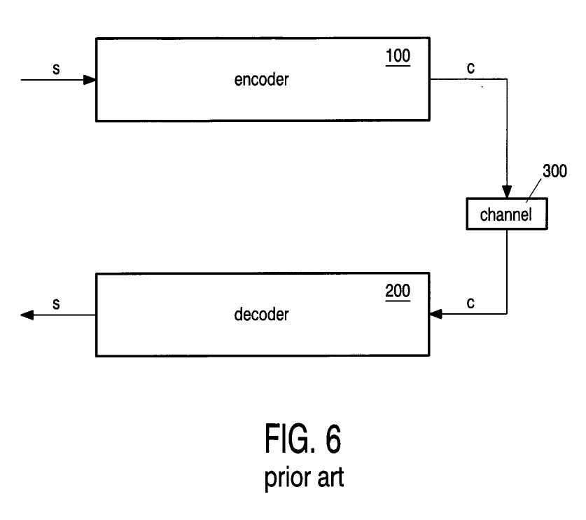

The invention relates to a modulation code system as shown in FIG. 6, including an encoder 100 for transforming an original signal s into an encoded signal c satisfying predefined second constraints before said signal being transmitted via a channel 300 or stored on a recording medium (not shown). This modulation code system further comprises a decoder 200 for decoding the encoded signal c, after restoration or receipt, back into the original signal s. The invention further relates to a decoder, encoder, signal and record carrier. Furthermore, the invention relates to a method of encoding and decoding.

Such a modulated code system known in the art is predominantly used in data transmission systems or data storage systems.

The invention further relates to known methods of operating the encoder 100 and the decoder 200.

In the following, reference is made to different signals, satisfying different constraints. The constraints are typically either simple or complicated. A signal satisfying simple constraints is e.g. a (0,k)-constrained signal, which is a binary signal where the number of consecutive zeros is at most k+1. A signal satisfying complicated constraints, however, is a signal obeying run length constraints on more complicated patterns, like e.g. the transition patterns of the anti-whistle patterns as listed in Table 1.

Traditionally, encoders or decoders of modulation code systems use specific modulation methods, e.g. the enumerative encoding method or the integrated scrambling method. The enumerative encoding method is e.g. known from K. A. S. Immink, “A practical method for approaching the channel capacity of constrained channels”, IEEE Trans. Inform. Theory, vol. IT-43, no. 5, pp. 1389-1399, September 1997. The integrated scrambling method is e.g. known from K. A. S. Immink, “Codes for mass data storage systems”, Shannon Foundation Publishers, The Netherlands, 1999.

Modulation codes such as (d,k)-codes and (d,k)-RLL codes are widely employed in digital transmission and storage systems. A modulation code consists of an encoder which servers to transform arbitrary sequences of source bits into sequences that obey certain constraints and a decoder to recover the original source from the constrained sequence. A binary sequence is said to be (d,k)-constrained if any two consecutive ones in the sequence are separated by at least d and at most k zeroes; it is said to be (d,k)-RLL constrained if the minimum and maximum run lengths are at least d+1 and at most k+1, respectively. The use of constrained sequences enables the data receiver to extract control information to be used for, for example, timing recovery, gain control, or equalization adaptation.

Many modern data receivers employ adaptive equalization or bandwidth control. In some CD or DVD systems, two-dimensional adaptive equalization is used to combat not only inter-symbol interference along the track but also inter-track interference (cross-talk cancellation). Also, in certain data receivers the only adaptive part is a circuit for slope control. In order for such systems to function properly, the frequency components of the received signal must obey certain constraints which in turn dictate(s?) the use of data sequences in which the maximum (nm) length of certain (periodic) data patterns is limited. As a typical example are mentioned constraints on data patterns of period 1 or 2 (k₁- and k₂-constraints) that are already used in practical systems. Periodic data patterns with a specific length will result in a whistle with a respective frequency. A known problem in receiving systems is that whistles in a received signal have a negative influence on the functioning of for example the PLLs in the receiver or gain control and thus on the reconstruction of the transmitted data. Therefore, there is a need to generate data sequences that do not generate sequences that could negatively influence the reconstruction of the transmitted data.

Hereafter some definitions are given to improve the understanding of the technical field.

A sequence is (k;p)-pattern-constrained if it does not contain a run of length k of the pattern p. What is given is a pattern p=(p₀p₁ . . . pₑ₋₁pₑ) which is interpreted as representing the periodic sequence . . . , p₀, p₁, . . . , pₑ₋₁, pₑ, p₀, p₁, . . . , pₑ₋₁, . . . of period e. A sequence is (k;P)-pattern constrained if the sequence is (kᵢ,p⁽ⁱ⁾)-constrained for all i, wherein k=k₁, . . . , kᵢ, which is a sequence of positive integers k, and P=, p⁽¹⁾, . . . p⁽ⁱ⁾, which is a sequence of periodic patterns. A sequence is P-pattern-constrained if it is (k;P)-pattern constrained for some k.

A k-constrained sequence is a binary sequence where the number of consecutive zeroes is at most k. These sequences are precisely the (k;p)-constrained sequences for the pattern p=(0).

A k-RLL-constrained sequence is a sequence with symbols from {−1,1}, thus a binary sequence, where the maximum run of each of the symbols is at most k+1. These sequences are precisely the (k;P)-pattern constrained sequences with k=k+1 and P=(−1), (1).

An anti-whistle constrained sequence is a pattern that has only a single frequency component in the pass band ranging from dc to the Nyquist frequency. Table 1 discloses some anti-whistle patterns and the corresponding index. Anti-whistle transition patterns are obtained by one time integrating/differentiating the anti-whistle pattern.

TABLE 1
Anti-whistle transition patterns.

| | anti- | period anti- | anti-whistle | period anti- |
|---|---|---|---|---|
| | whistle | whistle | transition | whistle transition |
| index | pattern | pattern | pattern | pattern |
| 1 | 0 | 1 | 0 | 1 |
| 2 | 01 | 2 | 1 | 1 |
| 4^{a} | 0011 | 4 | 01 | 2 |
| 4^{b} | 0111 | 4 | 0011 | 4 |
| 3 | 011 | 3 | 011 | 3 |
| 6 | 000111 | 6 | 001 | 3 |

These known methods of encoding/decoding enable the transformation of the original signal s into the signal c satisfying second constraints and back again, usually at a modulation code rate close to 1. The rate of a modulation code is a number that refers to the average number of encoded signals per source symbol: For example, an encoder of rate 1/2 code produces (on average) two encoded symbols for each source symbol.

At least the decoder of such known modulation code systems is usually implemented in hardware for enabling high-speed operation. However, hardware implementation of the above mentioned modulation code methods disadvantageously requires quite a lot of hardware, e.g. to store necessary tables. In the known modulation coders the relation between input words and corresponding output words is uniquely defined.

Based on that prior art it is the object of the invention to improve a known modulation code system, an encoder and a decoder as well as known methods of operating the encoder and the decoder such that their implementations require less hardware.

A modulation code system according to the invention comprises
a modulation code encoder (110) for coding the original signal s into an intermediate signal t satisfying predefined first constraints;
a transformer encoder (120) for converting said intermediate signal t in order to generate an encoded signal c satisfying a predefined second constraint
means for supplying the encoded signal c to a medium;
means for retrieving the encoded signal c from said medium;
a transformer decoder (220) for converting the encoded signal c so as to obtain said intermediate signal t and
a modulation code decoder (210) for decoding said intermediate signal t into said original signal s,
   wherein the transformer decoder (220) is adapted to convert a signal that violates the predefined second constraint into another signal that violates the predefined first constraint, the transformer decoder (220) having a polynomial function b(D), and the transformer encoder (120) having the polynomial function 1/b(D).

The invention is based on the following recognition. The first constraints of the modulation code encoder may in general be simpler, equally complicated or more complicated than the second constraints of the channel signal. However, in typical applications the first constraints are simpler than the second constraints. The signals that violate the second constraint are the signals that have a negative influence on the functioning of a receiver or playback apparatus. As a lot of effort is put into making the known encoders that generate the first constrained signal, it will take even more effort to adapt the encoders to make them comply with more complicated constraints, such as anti-whistle constraints. Normally, only a limited number of periodic signals have a negative influence on the functioning of PLLs or other control/servo circuits in a receiver or playback apparatus; these periodic signals will be referred to as forbidden signals. These forbidden signals should therefore not be generated and transmitted by the modulation code system. Furthermore, as the known encoder is arranged to generate constrained signals such as (0,k)-constrained signals, said encoders will not generate a lot of patterns, i.e. patterns that do not comply with the constraint. The number of patterns that do not comply with the constraint, and that will not be generated by the known encoders, is larger than the number of periodic signals that should not be generated. The transformer decoder is designed such that it transforms forbidden signals into signals that do not comply with the constraints of the encoder. Assume that the transformer decoder has the polynomial function b(D). By determining the inverse function of the transformer decoder, the polynomial function of the transformer encoder 1/b(D) can be determined. Said transformer encoder transforms signals that do not comply with the constraints of the modulation code encoder into the forbidden signals. In normal operation, the modulation code encoder will not generate signals that do not comply with the constraints of the modulation code encoder and therefore the transformer encoder according to the invention will not generate the forbidden signals. In a preferred embodiment the polynomial function b(D) is a linear polynomial function.

The claimed design of the modulation code system, in particular the series connection of the modulation code encoder with the transformer encoder within said encoder and the series connection of the transformer decoder with said modulation code decoder within said decoder, ensures that the hardware expense for implementing the encoder and the decoder is advantageously essentially reduced by making use of the benefits of the characteristics of the known modulation coders.

In a preferred embodiment of the invention, the predefined first constraint is a k-constraint and the predefined second constraint is at least an anti-whistle-constraint. Preferably the transformer encoder and transformer decoder are in the form of a linear feedback filter and linear filter, respectively. This type of filters can be easily implemented in hardware as well in software. The invention can be used in any kind of transmission or recording system which makes use of a known modulation coding system.

In a preferred embodiment of the invention, the modulation code encoder/decoder is a (0,k)-encoder; in that case the intermediate sequence t is (0,k)-constrained and thus satisfies a very simple constraint.

Further advantageous embodiments of both the encoder and the decoder are subject matter of the dependent claims.

The description is accompanied by six Figures, wherein

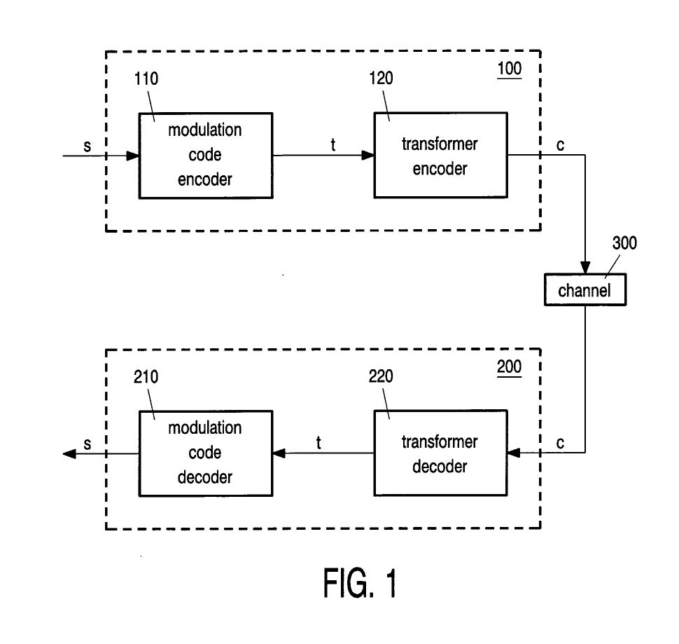

FIG. 1 shows a modulation code system according to the present invention;

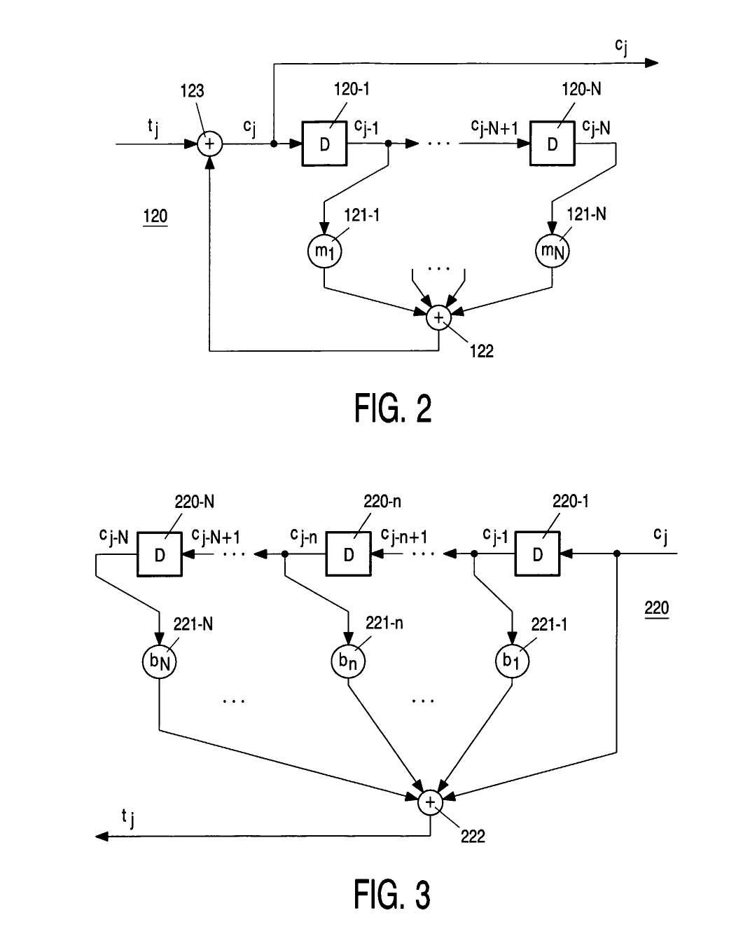

FIG. 2 shows a transformer encoder according to the present invention;

FIG. 3 shows a transformer decoder according to the present invention;

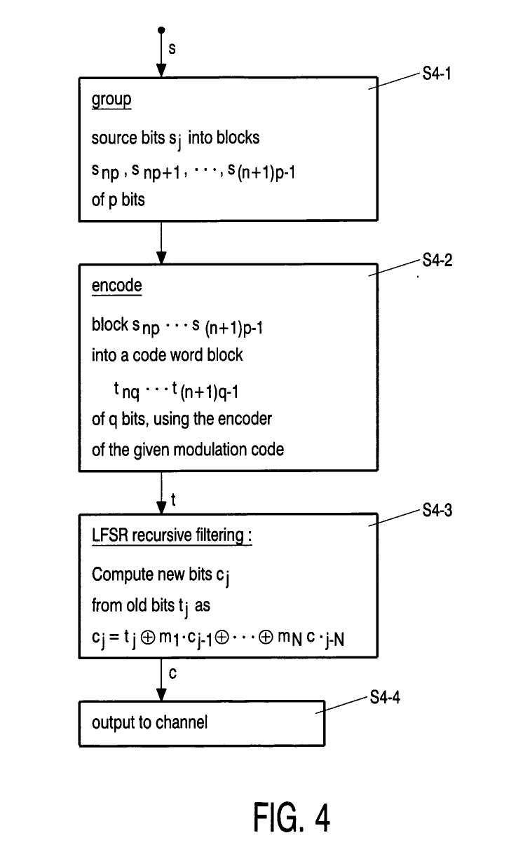

FIG. 4 shows a flow chart illustrating the operation of an encoder according to the present invention;

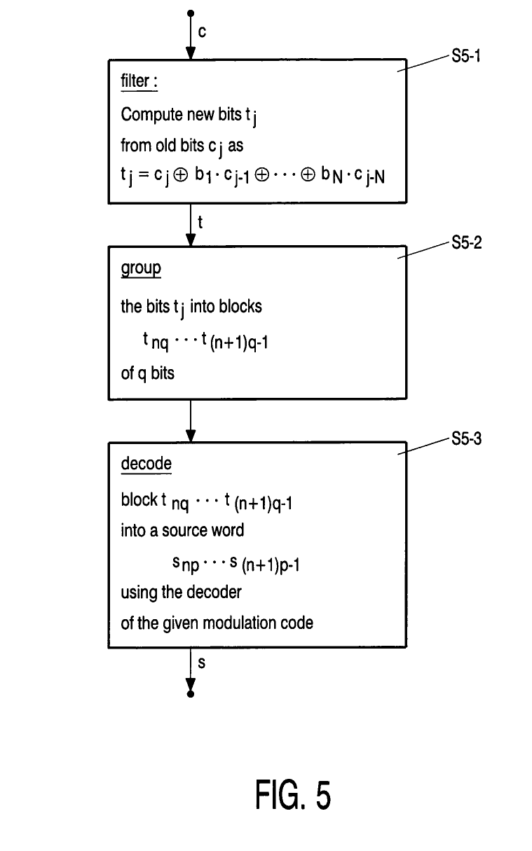

FIG. 5 shows a flow chart illustrating the operation of a decoder according to the present invention; and

FIG. 6 shows a modulation code system known in the art.

In the following, a preferred embodiment of the modulation code system according to the invention will be described in more detail by reference to FIGS. 1 to 5.

First the design of said modulation code system, in particular the design of the linear shift register 120 and of the sliding block decoder filter 220, will be described by reference to FIGS. 1 to 3.

FIG. 1 illustrates the design of the modulation code system. It comprises an encoder 100 for transforming an original signal s into an encoded signal c satisfying predefined second constraints, such as anti-whistle constraints. Said encoder 100 includes a series connection of a modulation code encoder 110 receiving said original signal s and a transformer encoder 120 for outputting said encoded signal c.

Said encoded signal c is e.g. transmitted via a channel 300 or stored on a recording medium (not shown). Any suitable recording medium can be used such as a Hard disk drive, optical disc, and flash memory.

After transmission via said channel 300, or after being restored from said recording medium, the encoded signal c is input to a decoder 200 of said modulation code system in order to re-generate said original signal s. To achieve this, the decoder 200 comprises a transformer decoder 220 for receiving said transmitted or restored encoded signal c and a modulation code decoder 210 being connected in series behind said sliding block decoder filter 200 in order to output said desired original signal s.

FIG. 2 shows a preferred embodiment of the transformer encoder 120 comprising a linear shift register. The linear shift register is represented by N delay elements 120-1, . . . , 120-N each of which may be embodied as a flip-flop. The delay elements 120-1, . . . 120-N are connected in series such that e.g. the bits cⱼ₋₁−c_{j-(N-1)} simultaneously output by said delay elements 120-1 to 120-(N−1), respectively, are input to the respective consecutive delay elements 120-2 to 120-N, respectively. Moreover, said transformer encoder 120 comprises N multiplier elements 121-1, . . . 121-N, each of which receiving another one of said N bits cⱼ₋₁−c_{j-N} output from said delay elements 122-1, . . . 122-N, respectively, and multiplying the received bits cⱼ₋₁−c_{j-N} by a constant m₁, . . . m_{N}, respectively, for generating N multiplier output signals. Said transformer encoder 120 further comprises a first XOR-gate 122 for receiving and XOR-combining said N multiplier output signals in order to generate a first XOR-output signal. Said first XOR-output signal is XOR-combined by a second XOR-gate 123 with bits tⱼ of a received intermediate signal t output by said modulation code encoder 110. Said intermediate signal t might be latched in a memory (not shown) before being input to said transformer encoder 120. At its output, said second XOR-gate 123 generates a second XOR-output signal representing the encoded signal c output by said transformer encoder 120. Said encoded signal c is input bitwise, i.e., bits cⱼ thereof are input into the first delay element 121-1 of said linear shift register 120-1, . . . 120-N.

The transformer encoder 120 is preferably embodied in hardware in order to enable a high operation speed.

FIG. 3 shows a sliding block decoder representing a preferred embodiment of the transformer decoder 220. In said embodiment the transformer decoder 220 comprises a linear shift register being represented by N delay elements 220-1, . . . , 220-N, each of which may be embodied as a flip-flop. N is an integer greater than 2. The delay elements 220-1, . . . 220-N are connected in series such that e.g. the output bits cⱼ₋₁−c_{j-(N-1)} of said delay elements 220-1 to 220-(N−1) are input to the respective consecutive delay elements 220-2 to 220-N, respectively. Moreover, said transformer decoder 220 comprises N multiplier elements 221-1, . . . 221-N, each of which receiving another one of said N bits cⱼ₋₁−c_{j-N} output from said delay elements 222-1, . . . 222-N, respectively, and multiplying the received bits cⱼ₋₁−c_{j-N} by a constant b₁, . . . b_{N}, respectively, for generating N multiplier output signals. Said transformer decoder 220 further comprises a XOR-gate 222 for receiving and XOR-combining said N multiplier output signals in order to regenerate the intermediate signal t having bits tⱼ.

Said transformer decoder 220 is preferably implemented in hardware in order to enable a high operation speed.

The intermediate signal t output by said transformer decoder 220 might be latched in a memory (not shown) before being input to said modulation code decoder 210.

In the following, the operation of the encoder 100 and of the decoder 200 will be explained in more detail by reference to FIGS. 4 and 5.

In FIG. 4 the operation of the modulation code encoder 110 and of the transformer encoder 120 are explained in more detail. More specifically, the modulation code encoder 110 receives the original input signal s the source bits sⱼ of which are grouped into blocks sₙₚ, sₙₚ₊₁, . . . , s₍ₙ₊₁₎ₚ₋₁ of p bits, respectively (see method step S4-1).

Subsequently, these blocks are encoded—according to method step S4-2—into a code word block t_{nq} . . . t_{(n+1)q-1} of q bits, respectively. Said encoding is done in the encoder 110 in order to generate the intermediate signal t by using a predetermined modulation code.

Said intermediate signal t is subsequently recursively filtered by said linear feedback shift register 120 in order to generate the encoded signal c. More specifically, in said shift register 120 each bit cⱼ of said encoded signal c is generated from a bit tⱼ of said intermediate signal t and of previously computed bits cⱼ₋ₙ according to the following recursive equation:

cⱼ=tⱼ⊕m₁·cⱼ₋₁⊕ . . . ⊕m_{N}·c_{jN}. (1)

wherein ⊕ indicates an XOR-operation in the case of binary signals and N is an integer preferably larger than 3.

Formula (1) represents the XOR-combination done by the first and the second XOR-gate 122, 123 as shown in FIG. 2 (method step S4-3).

Subsequently, the thus generated encoded signal c representing a sequence of said bits cⱼ is output to a channel 300 according to method step S4-4.

FIG. 5 illustrates the operation of the decoder 200. More specifically, according to method step S5-1 the sliding block decoder filter 220 sequentially receives the bits cⱼ of the encoded signal c, after transmission or after restoration, from the recording medium. In said sliding block decoder filter 220, the intermediate signal t is bitwise restored in step S5-1 by computing the respective bits tⱼ of said intermediate signal t according to the following equation:

tⱼ=cⱼ⊕b₁·cⱼ₋₁⊕ . . . ⊕b_{N}·c_{j-N} (2)

Said formula (2) represents the operation of the XOR-gate 222 as shown in FIG. 3.

Moreover, in said sliding block decoder the bits of said intermediate signal tⱼ⁰ are—according to method step S5-2—grouped into blocks t_{nq} . . . t_{(n+1)q-1} of q bits, respectively.

Finally, said blocks are decoded according to method step S5-3 into a source word sₙₚ, . . . , s_{n+1,p-1} of the original signal s. This decoding step S5-5 is done by using the modulation code decoder 210 of a predetermined modulation code.

It should be noted that in step S4-2 the encoding is carried out by a known modulation encoder, and in step S5-3 the decoding is carried out by a known modulation decoder.

In the following, mathematical background information is given about an appropriate design of the linear feedback shift register 120 and of the sliding block decoder filter 220 according to the invention. Hereinafter, the signals s, t and c are referred to as sequences s, t and c, respectively.

First a mathematical description is given of the transformer encoder 120 and the corresponding transformer decoder 220 as shown in FIG. 2 and FIG. 3.

Let F be a field (typically F=GF(2)). The finite field GF(2) consists of elements 0 and 1 which satisfy the following addition and multiplication rules:

0+0=0,0+1=1,1+0=1,1+1=0,

0×0=0,0×1=0,1×0=0,1×1=1.

Consider a sliding block decoder filter map φ of the form

$$φ ( {c}_{0} , … , {c}_{N} ) = {\sum }_{n = 0}^{N} {b}_{n} {c}_{N - n} . \qquad ( 3 )$$

Of course, we may assume without loss of generality that

b₀≠0. (4)

With such a map, we associate its window polynomial

$$b ( D ) = {\sum }_{n = 0}^{N} {b}_{n} {D}^{n}$$

in the delay operator D. With each sequence c over F, we associate the formal power series

$$c ( D ) = {\sum }_{j} {c}_{j} {D}^{j} .$$

Now, if the sequence t is the image of the sequence c under the block map φ, then

$${t}_{j} = φ ( {c}_{j - N} , … {c}_{j} ) = {\sum }_{n = 0}^{N} {b}_{n} {c}_{j - n} \qquad ( 5 )$$

so that t is the result of the convolution of c with b, that is,

t(D)=c(D)b(D).

Note that due to the condition (4), such a block map is indeed invertible. Indeed, if a sequence t is encoded into the sequence c by letting

$${c}_{j} = ( {t}_{j + s} - {\sum }_{n = 1}^{N} {b}_{n} {c}_{j - n} ) / {b}_{0} , \qquad ( 6 )$$

then c is decoded to t by the sliding block decoder with block map as in (5). From (6) it can be seen that the encoding operation is in fact linear feedback filtering with polynomial function 1/b(D). And the decoding operation is a linear filter operation with polynomial function b(D).

Let p=(p₀ . . . pₑ₋₁). The sequence c will be said to be (k;p)-pattern-constrained if no block of k+1 consecutive symbols from c is equal to one of the e blocks pᵢpᵢ₊₁ . . . pᵢ₊ₖ, i=0, . . . , e−1 (read indices modulo e if k≧e). Now the next problem is how to design the transformer encoder 120 and the transformer decoder 220, that is, how to choose the window polynomial b(D) so that the sequence c in FIG. 1 satisfies a (k′;p)-pattern constraint for some k′.

First, supposing that the simple constraint is a (0,k)-constraint, that is, supposing that the modulation code encoder 110 outputs a sequence t that is known not to contain a run of k+1 consecutive zeroes.

With the periodic pattern p=(p₀ . . . pₑ₋₁), the pattern polynomial

$$p ( D ) = {\sum }_{i = 0}^{e - 1} {p}_{i} {D}^{i}$$

is associated.

Supposing that the “window” of the sliding block decoder is entirely filled with the periodic pattern, that is, supposing that in equation (5), it is the case that cⱼ=p_{j+r mod e}, j=n−N, . . . , n, for some integer r. Then tⱼ is the (j+r mod e)′th coefficient of the polynomial b(D)p(D) mod D^{e}−1. From that it follows:

Lemma 1: The image of a pattern p=(p₀ . . . pₑ₋₁) under the block map with associated window polynomial b(D) is the zero-pattern if and only if p(D)b(D)=0 mod D^{e}−1, that is, if and only if b(D) is divisible by the polynomial

bₚ(D):=(D^{e}−1)/gcd(D^{e}−1,p(D)).

The function gcd is the function that determines the greatest common divisible polynomial of the corresponding polynomials.

The polynomial bₚ(D) in the above lemma will hereinafter be referred to as the (minimal) annihilator polynomial associated with the pattern p. What follows as a consequence of Lemma 1 is:

Theorem 2: Let P=(p⁽¹⁾, . . . p^{(r)}) denote a collection of periodic patterns. Let the polynomial bₚ(D) be defined as the least common multiple (1 cm) of the minimal annihilator polynomials of the patterns in P, that is,

$${b}_{p} ( D ) := lcm \{ {b}_{{p}^{( i )}} ( D ) \vert i = 1 , … , r \} .$$

Then all the periodic patterns from P are mapped onto the zero pattern under a block map with associated window polynomial b(D) if and only if b(D) is divisible by bₚ(D).

Corollary 1: The modulation code obtained as the concatenation of a k-constrained code and the rate-1 code obtained from an invertible linear block map with window polynomial b(D) satisfies a p-pattern-constraint if and only if bₚ(D) divides b(D). If that is the case, then it satisfies a (k+N,p)-pattern-constraint, where d denotes the degree of b(D).

The construction method implicit in Corollary 1 represents what in the whole specification is referred to as the recursive filtering method.

### EXAMPLE 1

The recursive filtering method will in this example be used to design a code for the anti-whistle constraints (see Table 2). It is worked over the GF(2). In Table 2 there are listed the binary anti-whistle patterns p, the associated window polynomials p(D), and the minimal annihilators bₚ(D) over GF(2). (There are listed all polarities for each pattern.) To check the entries in this table, note that since all computations are modulo 2, we have the following equations

D²−1≡(1+D)²;

D³−1≡(1+D)(1+D+D²);

D⁴−1≡(1+D)⁴.

D⁶−1(D³+1)²≡(1+D)²(1+D+D²)²

TABLE 2
Anti-whistle patterns with associated polynomials and annihilators.

| | binary | | pattern | minimal |
|---|---|---|---|---|
| index | pattern | period | polynomial | annihilator |
| 1(0) | 0 | 1 | 0 | 1 |
| 1(1) | 1 | 1 | 1 | 1 + D |
| 2 | 01 | 2 | 1 | (1 + D)² |
| 4^{a} | 0011 | 4 | 1 + D | (1 + D)³ |
| 4^{b}(0) | 1000 | 4 | 1 | (1 + D)⁴ |
| 4^{b}(1) | 0111 | 4 | 1 + D + D² | (1 + D)⁴ |
| 3(0) | 100 | 3 | 1 | (1 + D)(1D + D²) |
| 3(1) | 011 | 3 | 1 + D | 1 + D + D² |
| 6 | 000111 | 6 | 1 + D + D² | (1 + D)²(1 + D + D²) |

It can immediately be seen from Table 2 that the annihilator polynomial bₚ(D) for the collection P of anti-whistle patterns equals

bₚ(D)=(1+D)⁴(1+D+D²)≡1+D+D²+D⁴+D⁵+D⁶. (7)

So the recursive filter with polynomial function 1/bₚ(D) transforms a k-constrained sequence into an anti-whistle constrained sequence, where the run length of each anti-whistle pattern is at most k+6.

Finally, in order to investigate the efficiency of the method, the full set of patterns annihilated by the anti-whistle polynomial bₚ(D) in (7) shall be determined. Since both the polynomials

D⁴−1≡(1+D)⁴, D³−1≡(1+D)(1+D+D²)

divide the anti-whistle polynomial, it annihilates all patterns of period three and four. Also, since D¹²−1≡(D³−1)⁴≡(1+D)⁴(1+D+D²)⁴ is divisible by the anti-whistle polynomial, each annihilated pattern is also annihilated by D¹²−1, hence necessarily has period 12. Now if p is a pattern of period 12, then it is annihilated by the anti-whistle polynomial if and only if the associated pattern polynomial p(D) satisfies

p(D)bₚ(D)≡0 mod D¹²−1

over GF(2), which is the case if and only if

p(D)≡0 mod(1+D+D²)³.

If in fact p has a period smaller than 12, then it has period 4 (hence is annihilated) or period 6. Using a similar reasoning as before, a pattern of period 6 is annihilated if and only if its associated pattern polynomial p(D) satisfies p(D)=−0 mod 1+D+D².

It is now an easy exercise to determine all patterns that are annihilated by the anti-whistle polynomial. The following remark will further reduce the computations. In general, a pattern p of period e has in fact a smaller period e′, for some divisor e′ of e, if and only if its associated pattern polynomial p(D) is divisible by (D^{e}−1)/(D^{e′}−1)=1+D^{e′}+ . . . +D^{(q-1)e′}, where q=e/e′. For example, a pattern of smallest period 6 that is annihilated by the anti-whistle polynomial has an associated pattern polynomial of the form p(D)=(1+D+D²)a(D) with a(D) of degree at most 5 and not divisible by 1+D or by 1+D+D². Using this, it can be seen that the only patterns annihilated by the anti-whistle polynomial are the anti-whistle patterns together with some patterns of smallest period 12.

So, in this case, only a few additional, very weak constraints are introduced by the transformation coding and hence the efficiency of the overall modulation code almost equals the efficiency of the overall modulation code encoder 110 on which the overall code is based. Therefore, the invention is very suitable to be used with known encoders and decoders which have a modulation code rate close to 1, as it is very difficult to add new constraints to said known encoders and decoders

More generally, supposing that the simple constraint is a (k,a)-pattern-constraint for some pattern a=(a₀, a₁, . . . , a_{f-1}), then, in a simpler way, it follows that to get a (k′;p)-pattern-constraint for some k′, the polynomial b(D) must be chosen so that p(D)b(D)=a(D) mod D^{f}−1.

Although the invention is described with reference to preferred embodiments thereof, it is to be understood that these are non-limitative examples. Thus, various modifications are conceivable to those skilled in the art, without departing from the scope of the invention, as defined by the claims.

The use of the verb “to comprise” and its conjugations does not exclude the presence of elements or steps other than those stated in a claim. Furthermore, the use of the article “a” or “an” preceding an element does not exclude the presence of a plurality of such elements. In the claims, any reference signs placed between parentheses shall not be construed as limiting the scope of the claims. The invention may be implemented by means of hardware as well as software. The same item of hardware may represent several “means”. Furthermore, the invention resides in each and every novel feature or combination of features.

1. Modulation code system comprising a modulation code encoder (110) for coding the original signal s into an intermediate signal t satisfying predefined first constraints;
a transformer encoder (120) for converting said intermediate signal t in order to generate an encoded signal c satisfying a predefined second constraint means for supplying the encoded signal c to a medium;
means for retrieving the encoded signal c from said medium;
a transformer decoder (220) for converting the encoded signal c so as to obtain said intermediate signal t and
a modulation code decoder (210) for decoding said intermediate signal t into said original signal s, wherein the transformer decoder (220) is adapted to convert a signal that violates the predefined second constraint into another signal that violates the predefined first constraint, the transformer decoder (220) having a polynomial function b(D), and the transformer encoder (120) having the polynomial function 1/b(D).

2. The modulation code system as claimed in claim 1, wherein the predefined first constraint is a k-constraint and the predefined second constraint is at least an anti-whistle-constraint.

3. The modulation code system as claimed in claim 1, wherein the transformer encoder is in the form of a linear feedback filter.

4. The modulation code system as claimed in claim 1, wherein the transformer encoder is in the form of a linear filter.

5. The modulation code system as claimed in claim 1, wherein the medium is a record carrier.

6. The modulation code system as claimed in claim 1, wherein the medium is a transmission medium.

7. A decoder (200) for use in the modulation code system as claimed in claim 1, for retrieving an original signal s from an encoded signal c, the decoder comprising
a transformer decoder (220) for filtering the encoded signal c in order to generate an intermediate signal t; and
a modulation code decoder (210) for decoding said intermediate signal t into said original signal s, wherein the transformer decoder (220) is adapted to convert a signal that violates a predefined second constraint into another signal that violates a predefined first constraint, the transformer decoder (220) having a polynomial function b(D).

8. The decoder as claimed in claim 7, wherein the predefined first constraint is a k-constraint and the predefined second constraint is at least an anti-whistle-constraint.

9. The decoder as claimed in claim 7, wherein the transformer decoder is in the form of a linear filter.

10. The decoder (200) according to claim 7, characterized in that the transformer decoder (220) is embodied as a sliding block decoder filter comprising
a linear shift register consisting of N delay elements (220-1, . . . , 220-N) being connected in series, wherein the first delay element (220-1) of said series connection receives the encoded signal c after transmission or restoration and wherein the output signals of the first N−1 delay elements (220-1, . . . , 220-(N−1)) are input to the respective consecutive delay elements (220-2, . . . , 220-N);
N multiplier elements (221-1, . . . , 221-N) each of which receiving another one of said N output signals of said delay elements (222-1, . . . , 222-N) and multiplying the received delay output signal by a given constant (b₁, . . . , b_{N}) for generating a respective multiplier output signal; and
a XOR-gate (222) for receiving and XOR-combining said N multiplier output signals and said encoded signal c in order to generate the intermediate signal t as output by the transformer decoder (220), N being an integer larger than 2.

11. The decoder (200) according to claim 7, characterized in that the transformer decoder (220) is implemented at least partly in software or hardware.

12. The decoder (200) according to claim 7, characterized in that the decoder (200) has a modulation code rate close to 1.

13. The decoder (200) according to claim 7, characterized in that the modulation code decoder (210) is a (0,k)-decoder.

14. Decoding method of decoding an encoded signal c satisfying predetermined second constraints into an original signal; characterized by the following steps:
filtering the encoded signal c by means of the polynomial function 1/b(D) in order to generate an intermediate signal t satisfying predetermined first constraints, wherein b(D) is a polynomial function that converts a signal that violates the predefined second constraints into another signal that violates the predefined first constraints; and
decoding the intermediate signal t into the original signal s.

15. An encoder (100) for use in the modulation code system as claimed in claim 1, wherein the encoder comprises
a modulation code encoder (110) for transforming the original signal s into the intermediate signal t satisfying predefined first constraints; and
the transformer encoder (120) has the polynomial function 1/b(D) for filtering said intermediate signal t in order to generate said encoded signal c satisfying predefined second constraints, wherein b(D) is a polynomial function that converts a signal that violates the predefined second constraints into another signal that violates the predefined first constraints.

16. The encoder as claimed in claim 15, wherein the predefined first constraint is a k-constraint and the predefined second constraint is at least an anti-whistle-constraint.

17. The encoder as claimed in claim 15, wherein the transformer encoder is in the form of a linear feedback filter.

18. The encoder (100) according to claim 15, characterized in that the transformer encoder (120) comprises
a linear shift register consisting of N delay elements (120-n with n=1−N) being connected in series such that the output signals of the N−1 delay elements (120-1 to 120-(N−1)) are input to the consecutive delay element (120-2 to 120-N), respectively;
N multiplier elements (121-n) each of which receiving another one of said N output signals of said delay elements (122-1, . . . , 122-N) and multiplying the received delay element output signal with a constant (m₁, . . . m_{N}) for generating a respective multiplier output signal;
a first XOR-gate (122) for receiving and XOR-combining said N multiplier output signals in order to generate a first XOR-output signal; and
a second XOR-gate (123) for XOR-combining the intermediate signal t output by said modulation code encoder 110 with said first XOR-output signal in order to generate a second XOR-output signal which corresponds to the encoded signal c output by said transformer encoder (120) and which is input to the first delay element (120-1) of said series connection of delay elements (121-1, . . . , 120-N), N being an integer larger than 2.

19. The encoder (100) according to claim 15, characterized in that the transformer encoder (120) is implemented in software or hardware.

20. The encoder according to claim 15, characterized in that the encoder (100) has a modulation code rate close to 1.

21. The encoder according to claim 15, characterized in that the modulation code encoder (110) is a (0,k)-encoder.

22. Encoding method for transforming an original signal s into an encoded signal c satisfying predefined second constraints;
characterized by the following steps:
transforming the original signal s into an intermediate signal t satisfying predefined first constraints; and
filtering the intermediate signal t by means of the polynomial function 1/b(D) in order to generate an encoded signal c satisfying predefined second constraints, wherein b(D) is a polynomial function that converts a signal that violates the predefined second constraints into another signal that violates the predefined first constraints.

23. Encoded signal obtained with the encoding method according to claim 22.

24. Record carrier carrying the encoded signal obtained with the encoding method according to claim 22.
